(19) United States
(12) Patent Application Publication
(10) Pub. No.: US 2024/0327656 A1
(43) Pub. Date: Oct. 3, 2024

(54) CURABLE COMPOSITION, CURED LAYER USING THE COMPOSITION, AND DISPLAY DEVICE INCLUDING THE CURED LAYER

(71) Applicant: SAMSUNG SDI CO., LTD., Yongin-si (KR)

(72) Inventors: Jonggi KIM, Suwon-si (KR); Hyunsook JANG, Suwon-si (KR); Minsung KIM, Suwon-si (KR); Jiyoung JEONG, Suwon-si (KR); Mingi KIM, Suwon-si (KR); Gyeongseo MIN, Suwon-si (KR); Bumjin LEE, Suwon-si (KR)

(21) Appl. No.: 18/617,554

(22) Filed: Mar. 26, 2024

(30) Foreign Application Priority Data
Mar. 29, 2023 (KR) 10-2023-0041363

(51) Int. Cl. C09D 5/22; B82Y 20/00; B82Y 40/00; C08F 122/10; C08K 3/22; C08K 5/5419; C08K 13/02; C08K 13/06; C09D 4/00; C09D 7/40; C09D 7/62; C09D 7/63; C09D 135/02

(52) U.S. Cl. CPC C09D 5/22; C08F 122/1006; C08K 13/06; C09D 4/00; C09D 7/62; C09D 7/63; C09D 7/67; C09D 135/02; B82Y 20/00; B82Y 40/00; C08K 2003/2241; C08K 5/5419; C08K 13/02; C08K 2201/011

(57) ABSTRACT

A curable composition includes (A) quantum dots; (B) a polymerizable compound; and (C) a compound represented by Chemical Formula 1 having a weight average molecular weight of less than or equal to about 300 g/mol. A cured layer may be produced utilizing the curable composition, and a display device including the cured layer may be manufactured.

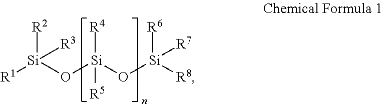

wherein in Chemical Formula 1, each substituent is as defined in the specification.

### CROSS-REFERENCE TO RELATED APPLICATION

The present application claims priority to and the benefit of Korean Patent Application No. 10-2023-0041363 filed on Mar. 29, 2023, in the Korean Intellectual Property Office, the content of which in its entirety is herein incorporated by reference.

### BACKGROUND OF THE INVENTION

### 1. Field

One or more aspects of embodiments of this disclosure are directed toward a curable composition, a cured layer utilizing the composition, and a display device including the cured layer.

### 2. Description of Related Art

In the case of comparable quantum dots, due to surface characteristics having hydrophobicity, a solvent in which the quantum dots may be suitably dispersed is limited, and thus, it may be difficult to introduce the quantum dots into a polar system including components such as a binder and/or a curable monomer.

For example, even in the case of a quantum dot ink composition that is currently being actively researched, a polarity of the composition may be relatively low in an initial step (e.g., before being dispersed), and so it may be dispersed in a solvent utilized in a curable composition having a relatively high hydrophobicity. However, in this case, it may be difficult to achieve a content of 20 wt % or more of quantum dots, based on a total amount of the composition, i.e., wt % or more of quantum dots may not be included (or may be difficult to include) in the composition, and thus it may be impossible or least very difficult to increase light efficiency of the ink over a set or certain level. Although the quantum dots may be additionally added and dispersed in order to (e.g., in an effort to) increase light efficiency, in this case, viscosity may exceed a set range (e.g., about 12 centipoise (cPs)) capable of ink-jetting and thus processability may not be satisfied or may not be suitable.

To achieve a suitable viscosity range capable of ink-jetting, a method of lowering an ink solid content (e.g., amount) by dissolving 50 wt % or more of a solvent based on a total amount of the composition may be utilized, and the method may provide a suitable result in terms of viscosity. However, even if suitable viscosity is achieved, nozzle drying due to solvent volatilization, nozzle clogging, and/or a thickness reduction of single film as time passes after jetting may become worse and it may become difficult to control thickness deviation after curing. Thus, the comparable (e.g., related art) quantum dot composition may be difficult to apply (or may not be applicable) to actual manufacturing processes.

Therefore, a solvent-free quantum dot ink that does not include a solvent is desired as it is a suitable (e.g., the most desirable) form to be applied to an actual manufacturing process. The current technique of applying a quantum dot itself to a solvent-type or kind composition is now limited to a certain extent.

For a solvent-free curable composition including quantum dots, it is necessary or desirable to develop a composition capable of suitably controlling dispersibility and satisfying jetting processability by surface-modifying the quantum dots with hydrophobic characteristics. In a comparable solvent-free curable composition including a high content (e.g., amount) of quantum dots, which has emerged in order to reduce nozzle drying due to volatilization of a solvent and thickness deviation of a single film, dispersibility, thermal stability, and photocurability of the curable composition are determined by factors such as efficiency of the quantum dots, which are a main light emitting element, and a composition design among (e.g., along with) the quantum dots, for example, ligands for surface-modifying the quantum dots, polymerizable monomers, and other components. The quantum dots have hydrophobicity due to one or more inorganic components of core and/or shell and an organic material of a ligand utilized for a surface treatment, and a different light emitting wavelength according to the inorganic composition and size. Recently, properties required or desired of a single film specimen utilizing a quantum dot-containing curable composition for a display is relatively high efficiency, relatively low viscosity, relatively low or reflectance, and/or relative ease of processing (e.g., relatively low outgas characteristics).

### SUMMARY OF THE INVENTION

One or more aspects of embodiments of the present disclosure are directed toward a curable composition capable of achieving a relatively low viscosity and a relatively low reflectance characteristics concurrently (e.g., simultaneously).

One or more embodiments are directed toward a cured layer produced utilizing the curable composition.

One or more embodiments are directed toward provides a display device including the cured layer.

One or more embodiments provide a curable composition including (A) quantum dots; (B) a polymerizable compound; and (C) a compound represented by Chemical Formula 1 having a weight average molecular weight of less than or equal to about 300 g/mol.

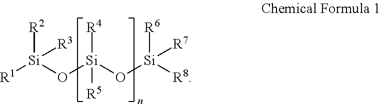

In Chemical Formula 1,

R¹ to R⁸ are each independently a hydrogen atom, a hydroxy group, an amine group, a substituted or unsubstituted C1 to C20 alkyl group, a substituted or unsubstituted C3 to C20 cycloalkyl group, or a substituted or unsubstituted C6 to C20 aryl group, and
n is an integer of 0 or 1.

In Chemical Formula 1, R¹ to R⁸ may each independently be a substituted or unsubstituted C1 to C20 alkyl group.

In Chemical Formula 1, n may be an integer of 0.

The compound represented by Chemical Formula 1 may have a weight average molecular weight of about 162 g/mol to about 300 g/mol.

The compound represented by Chemical Formula 1 may be included in an amount of about 1 wt % to about 15 wt % based on a total amount of the curable composition.

The polymerizable compound and the compound represented by Chemical Formula 1 may be included in a weight ratio of about 95:5 to about 80:20.

The polymerizable compound may be represented by Chemical Formula 2.

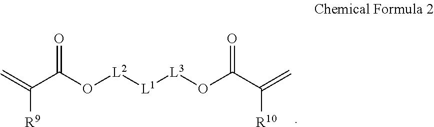

In Chemical Formula 2,
L¹ is a substituted or unsubstituted C1 to C10 alkylene group, a substituted or unsubstituted C3 to C20 cycloalkylene group, or an ether group (*—O—*),
L² and L³ are each independently a single bond or a substituted or unsubstituted C1 to C10 alkylene group, and
R⁹ and R¹⁰ are each independently a hydrogen atom, a substituted or unsubstituted C1 to C20 alkyl group, a substituted or unsubstituted C3 to C20 cycloalkyl group, or a substituted or unsubstituted C6 to C20 aryl group.

The curable composition may be a solvent-free curable composition.

The solvent-free curable composition may include about 5 wt % to about 60 wt % of (A) quantum dots; about 30 wt % to about 85 wt % of the (B) polymerizable compound; and about 1 wt % to about 15 wt % of the (C) compound represented by Chemical Formula 1 based on a total amount of the solvent-free curable composition.

The curable composition may further include a polymerization initiator, a light diffusing agent, a polymerization inhibitor, or a combination thereof.

The light diffusing agent may include barium sulfate, calcium carbonate, titanium dioxide, zirconia, or a combination thereof.

The curable composition may further include a solvent.

The curable composition may further include malonic acid; 3-amino-1,2-propanediol; a silane-based coupling agent; a leveling agent; a fluorine-based surfactant; or a combination thereof.

One or more embodiments provide a cured layer produced utilizing the curable composition.

The cured layer may have a reflectance measured by a specular component excluded (SCE) method of less than or equal to about 25%.

One or more embodiments provide a display device including the cured layer.

Other embodiments of the present disclosure are included in the following detailed description.

By adding an additive having a *—Si—O—Si—* group, having a relatively very low dynamic viscosity and a relatively low surface tension, and having a weight average molecular weight of less than or equal to 900 g/mol in the quantum dot-containing curable composition, the viscosity and the reflectance (e.g., both reflectance measured by a specular component included (SCI) method and reflectance measured by a specular component excluded (SCE) method) of the quantum dot-containing curable composition may be lowered.

### DETAILED DESCRIPTION

Hereinafter, embodiments of the present disclosure are described in more detail. However, these embodiments are provided as examples, the present disclosure is not limited thereto and the present disclosure is defined by the scope of the appended claims and their equivalents.

As utilized herein, if (e.g., when) specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As utilized herein, if (e.g., when) specific definition is not otherwise provided, “substituted” refers to replacement of at least one hydrogen atom by a substituent selected from a halogen atom (F, Cl, Br, and/or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As utilized herein, if (e.g., when) specific definition is not otherwise provided, “hetero” refers to inclusion of at least one heteroatom of N, O, S, or P, in the chemical formula.

As utilized herein, if (e.g., when) specific definition is not otherwise provided, “(meth)acrylate” refers to both (e.g., simultaneously) “acrylate” and “methacrylate”, and “(meth)acrylic acid” refers to “acrylic acid” and “methacrylic acid.”

As utilized herein, if (e.g., when) specific definition is not otherwise provided, the term “combination” refers to mixing and/or copolymerization.

As utilized herein, if (e.g., when) a definition is not otherwise provided, hydrogen is bonded at the position where a chemical bond is not drawn in chemical formula where it otherwise is supposed to be.

In some embodiments, in the present specification, if (e.g., when)if a definition is not otherwise provided, “*” refers to a linking point (e.g., a binding site) with the same or different atom or chemical formula.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, each component constituting the curable composition according to one or more embodiments will be described in more detail.

Recently, technological development has been made in the direction of improving light efficiency by surface-modifying quantum dots to lower viscosity of a quantum dot-containing solvent-free curable composition, and by introducing a polymerizable monomer having a relatively low molecular weight thereinto, but designing the polymerizable monomer to include a thiol group to secure high refractive characteristics thereof. In addition, to the quantum dot-containing solvent-free curable composition, in order (or in an effort) to increase efficiency of absorbed photons, a light diffusing agent (light scatterer) may be added with a size of tens to hundreds of nanometers, which scatters light at a size of 1/n of a wavelength in its set or specific emission path. Because the light diffusing agent has a larger particle size than the quantum dots with several to tens of nanometers, dispersion stability is required or desired due to the particle size difference between light diffusing agent and quantum dots, and in addition, relevant polarity and miscibility of the composition, if (e.g., when) designing a composition, should be considered.

However, if (e.g., when) an organic material with a relatively low molecular weight is introduced as the polymerizable monomer, there may arise a problem of generating outgas due to thermal decomposition in a thermal process during the manufacture of a single film, and further, because there may be issues of increasing viscosity and also, increasing diffuse reflection due to a metal material included in the light diffusing agent such as Ti and/or the like, the polymerizable monomer having a low molecular weight may not be easily or suitably introduced into the quantum dot-containing curable composition.

Accordingly, the present inventors, after a long study under this background, have achieved a suitably low viscosity of about 23 cps or less at room temperature (about 20° C. to about 25° C.) and improved light efficiency by introducing an additive having dynamic viscosity characteristics, suitably low surface tension, a suitably low weight average molecular weight, and a *—Si—O—Si—* group; have also produced a Si—O—Ti bridge due to a cascade reaction (e.g., chain reaction) with the surface of the light diffusing agent in the thermal process and improved the outgas generation according to the introduction of the low molecular weight material by controlling a silicon carbide radical reaction, and further, have developed a quantum dot-containing curable composition capable of minimizing or reducing the diffuse reflection according to an increase in a metal content (e.g., amount) of Ti and/or the like by matching refractive indices of Ti—Si.

(C) Compound Represented by Chemical Formula 1 Having Weight Average Molecular Weight of Less than or Equal to about 300 g/Mol

A curable composition according to one or more embodiments includes a compound represented by Chemical Formula 1 having a weight average molecular weight of less than or equal to about 300 g/mol.

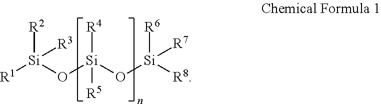

In Chemical Formula 1,
R¹ to R⁸ may each independently be a hydrogen atom, a hydroxy group, an amine group, a substituted or unsubstituted C1 to C20 alkyl group, a substituted or unsubstituted C3 to C20 cycloalkyl group, or a substituted or unsubstituted C6 to C20 aryl group, and
n is an integer of 0 or 1.

The compound represented by Chemical Formula 1 has a relatively very or substantially low dynamic viscosity (about 0.65 cst), relatively low surface tension (about 15.9 mN/m), relatively fast electron mobility (about 22 cm²/Vs2), and it may be possible to implement a viscosity reduction effect of greater than or equal to about 7 cps compared to the viscosity of a comparable quantum dot-containing curable composition.

For example, R¹ to R⁸ may each independently be a substituted or unsubstituted C1 to C20 alkyl group.

For example, n may be an integer of 0.

The compound represented by Chemical Formula 1 may have a weight average molecular weight of about 162 g/mol to about 300 g/mol. If (e.g., when) the compound represented by Chemical Formula 1 is greater than 300 g/mol, an effect of improving light efficiency may decrease, and the viscosity of the composition may increase, making it unsuitable for an inkjet process.

The compound represented by Chemical Formula 1 may be included in an amount of about 1 wt % to about 15 wt %, for example, about 2 wt % to about 12 wt %, based on a total amount of the curable composition. If (e.g., when) the content (e.g., amount) of the compound represented by Chemical Formula 1 is outside of the above range, problems such as a decrease in light efficiency, an increase in viscosity, and/or an irregular reflectance may occur.

According to some embodiments, the compound represented by Chemical Formula 1 should be utilized together with a polymerizable compound described herein below, and in some embodiments, a mixing weight ratio between the compound represented by Chemical Formula 1 and the polymerizable compound may also be important in terms of viscosity control and/or reflectance reduction. For example, the polymerizable compound and the compound represented by Chemical Formula 1 may be included in a weight ratio of about 95:5 to about 80:20.

### (B) Polymerizable Compound

The quantum dot-containing curable composition according to one or more embodiments includes a polymerizable compound, and may improve optical characteristics of the curable composition, and further, a mixing ratio between the curable composition and the compound represented by Chemical Formula 1 is controlled or selected according to the present embodiments, thereby satisfying (or achieving) a reflectance reduction effect.

For example, the polymerizable compound may have a carbon-carbon double bond at its terminal end.

The polymerizable compound having the carbon-carbon double bond at the terminal end may be included in an amount of about 30 wt % to about 85 wt %, for example, about 35 wt % to about 80 wt %, based on a total amount of the solvent-free curable composition. If the polymerizable compound having the carbon-carbon double bond at the terminal end is included within any of the above ranges, a solvent-free curable composition having a suitable viscosity that enables ink-jetting may be prepared, and the quantum dots in the prepared solvent-free curable composition may have improved dispersibility, thereby improving optical characteristics.

For example, the polymerizable compound having the carbon-carbon double bond at the terminal end may have a molecular weight of about 170 g/mol to about 1,000 g/mol. If the polymerizable compound having the carbon-carbon double bond at the terminal end has a molecular weight within the above range, it may be advantageous for ink-jetting because it does not increase (e.g., reduces an increase in) a viscosity of the composition without hindering (or substantially hindering) optical characteristics of the quantum dots.

For example, the polymerizable compound having the carbon-carbon double bond at the terminal end may be represented by Chemical Formula 2, but is not necessarily limited thereto.

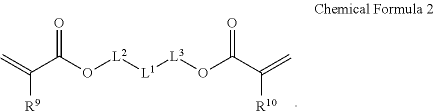

In Chemical Formula 2,
L¹ may be a substituted or unsubstituted C1 to C10 alkylene group, a substituted or unsubstituted C3 to C20 cycloalkylene group, or an ether group (*—O—*),
L² and L³ may each independently be a single bond or a substituted or unsubstituted C1 to C10 alkylene group, and
R⁹ and R¹⁰ may each independently be a hydrogen atom, a substituted or unsubstituted C1 to C20 alkyl group, a substituted or unsubstituted C3 to C20 cycloalkyl group, or a substituted or unsubstituted C6 to C20 aryl group.

For example, the polymerizable compound having a carbon-carbon double bond at the terminal end may be represented by Chemical Formula 2-1 or 2-2, but is not necessarily limited thereto.

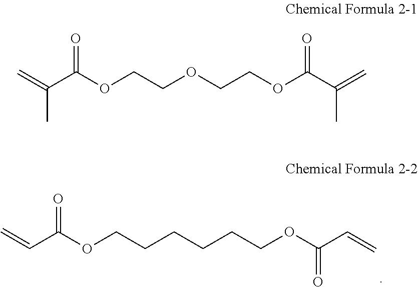

For example, in addition to the compound represented by Chemical Formula 2-1 or Chemical Formula 2-2, the polymerizable compound having the carbon-carbon double bond at the terminal end may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolacepoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof.

In some embodiments, in addition to the polymerizable compound having the carbon-carbon double bond at the terminal end, a suitable monomer utilization in thermosetting and/or photocurable compositions may be further included, and for example, the monomer may further include an oxetane-based compound such as bis[1-ethyl(3-oxetanyl)]methyl ether.

In some embodiments, if (e.g., when) the curable composition includes a solvent, the polymerizable compound may be included in an amount of about 1 wt % to about 20 wt %, about 1 wt % to about 15 wt %, for example, about 5 wt % to about 15 wt %, based on a total amount of the curable composition. If (e.g., when) the polymerizable compound is included within any of the above ranges, optical characteristics of the quantum dots may be improved.

### (A) Quantum Dots

For example, the quantum dots may have a maximum fluorescence emission wavelength at about 500 nm to about 680 nm.

For example, if (e.g., when) the curable composition according to one or more embodiments is a solvent-free curable composition, the quantum dots may be included in about 5 wt % to about 60 wt %, for example about 15 wt % to about 55 wt %, for example about 20 wt % to about 50 wt %, for example about 25 wt % to about 45 wt %. If the quantum dots are included within any of the above ranges, a suitably high light retention rate and/or light efficiency can be achieved even after curing.

For example, if (e.g., when) the curable composition according to one or more embodiments is a curable composition including a solvent, the quantum dots may be included in an amount of about 1 wt % to about 40 wt %, for example about 3 wt % to about 30 wt %, based on a total amount of the curable composition. If the quantum dots are included within any of the above ranges, the light conversion rate is improved and pattern characteristics and development characteristics are not impaired (or are not substantially impaired), so that excellent or suitable processibility may be obtained.

For example, the quantum dots absorb light in a wavelength region of about 360 nm to about 780 nm, for example about 400 nm to about 780 nm and emit fluorescence in a wavelength region of about 500 nm to about 700 nm, for example about 500 nm to about 580 nm, or emit fluorescence in a wavelength region of about 600 nm to about 680 nm. For example, the quantum dots may have a maximum fluorescence emission wavelength (fluorescence λₑₘ) at about 500 nm to about 680 nm.

The quantum dots may each independently have a full width at half maximum (FWHM) of about 20 nm to about 100 nm, for example about 20 nm to about 50 nm. If the quantum dots have a full width at half maximum (FWHM) of any of the above ranges, color reproducibility is increased if (e.g., when) utilized as a color material in a color filter due to suitably high color purity.

The quantum dots may each independently be an organic material, an inorganic material, or a hybrid (mixture) of an organic material and an inorganic material.

The quantum dots may each independently be composed of a core and a shell around (e.g., surrounding) the core, and the core and the shell may each independently have a structure of a core, core/shell, core/first shell/second shell, alloy, alloy/shell, and/or the like, and may be composed of Group II-IV, Group Ill-V compounds, and/or the like, but are not limited thereto.

For example, the core may include at least one material selected from among CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell around (e.g., surrounding) the core may include at least one material selected from among CdSe, ZnSe, ZnS, ZnTe, CdTe, PbS, TiO, SrSe, HgSe, and an alloy thereof, but is not necessarily limited thereto.

In one or more embodiments, because of increased environmental concerns around the world and fortified restrictions on toxic materials, a cadmium-free light emitting material (e.g., InP/ZnS, InP/ZnSe/ZnS, etc.) having lower quantum efficiency (quantum yield) but being suitably environmentally-friendly may be utilized instead of a light emitting material having a cadmium-based core.

In the case of the quantum dots having the core/shell structure, an entire size including the shell (e.g., an average particle diameter) may be about 1 nm to about 15 nm, for example, about 5 nm to about 15 nm.

For example, the quantum dots may each independently include red quantum dots, green quantum dots, or a combination thereof. The red quantum dots may each independently have an average particle diameter of about 10 nm to about 15 nm. The green quantum dots may each independently have an average particle diameter of about 5 nm to about 8 nm.

In some embodiments, for dispersion stability of the quantum dots, the curable composition according to one or more embodiments may further include a dispersant. The dispersant helps achieve substantially uniform dispersibility of light conversion materials such as quantum dots in the curable composition and may include a non-ionic, anionic, and/or cationic dispersant. For example, the dispersant may be polyalkylene glycol and/or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and/or the like, and they may be utilized alone or in a mixture of two or more. The dispersant may be utilized in an amount of about 0.1 wt % to about 100 wt %, for example about 10 wt % to about 20 wt % based on a solid content (e.g., amount) of the light conversion material such as quantum dots.

For example, the quantum dots may be quantum dots that are surface-modified with a ligand having a polar group, for example, a ligand having high affinity with the polymerizable compound. In the case of the surface-modified quantum dots as described above, it is very easy (or suitable) to prepare a high-concentration and/or highly-concentrated quantum dot dispersion (improvement of the dispersibility of the quantum dots for a polymerizable compound), which may have a great (e.g., positive) effect on improving light efficiency, and may be especially desirable in the realization of a solvent-free curable composition.

For example, the ligand having the polar group may have a structure having a relatively high affinity with the chemical structure of the polymerizable compound.

For example, the ligand having the polar group may be represented by any one of (e.g., at least one of) the compounds represented by Chemical Formulae A to Q, but is not necessarily limited thereto.

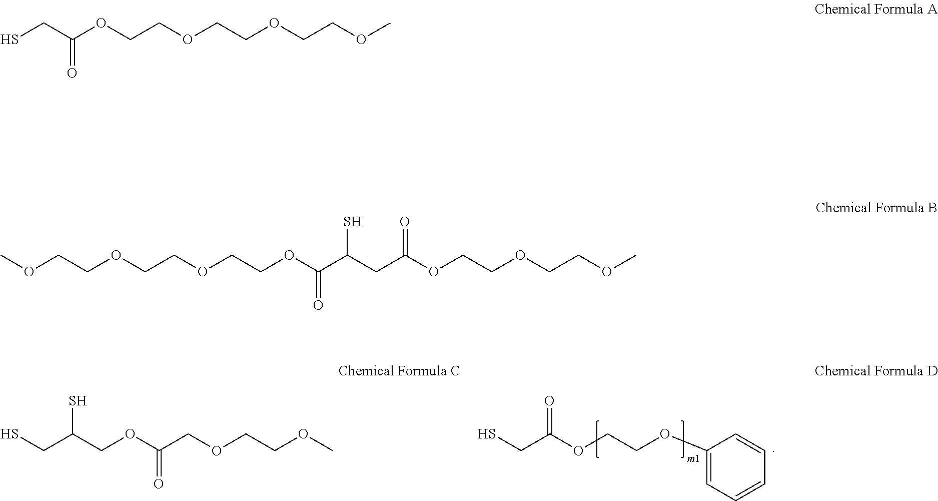

In Chemical Formula D, m1 is an integer from 0 to 10.

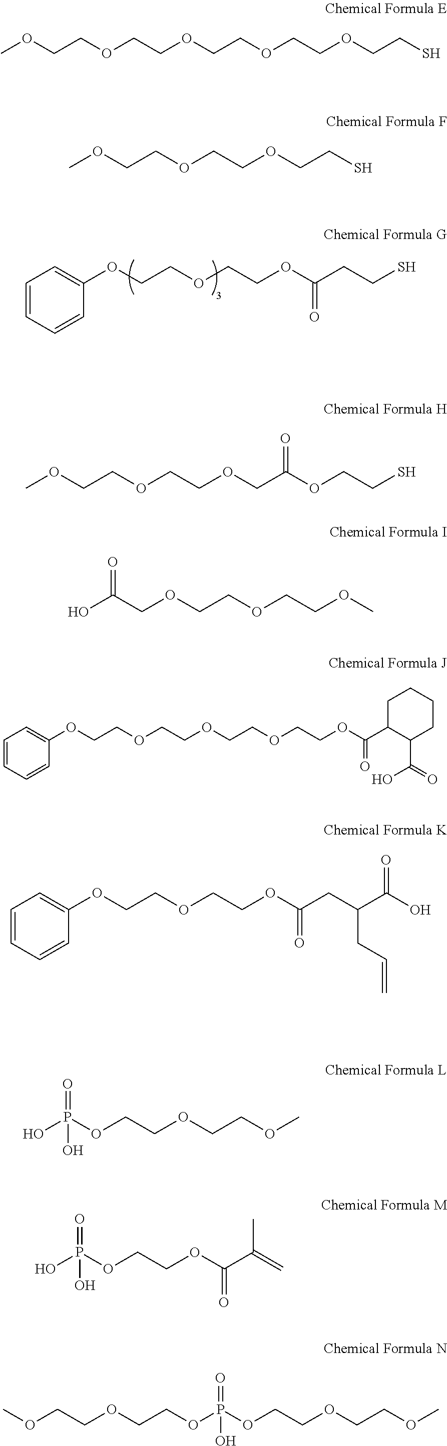

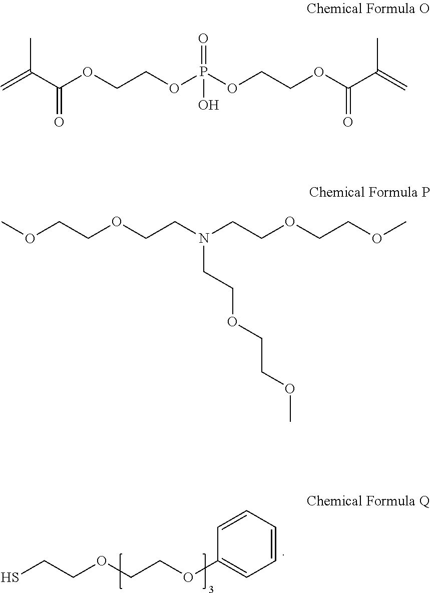

If (e.g., when) the ligand is utilized, the surface modification of the quantum dots is easier or suitable, and if (e.g., when) the quantum dots surface-modified with the ligand are added to the above-described polymerizable compound and stirred, a very transparent (e.g., suitably transparent) dispersion may be obtained, which indicates that the surface modification of the quantum dots is very good or suitable.

### Light Diffusing Agent

The curable composition according to one or more embodiments may further include a light diffusing agent.

For example, the light diffusing agent may include barium sulfate (BaSO₄), calcium carbonate (CaCO₃), titanium dioxide (TiO₂), zirconia (ZrO₂), or a combination thereof.

The light diffusing agent may reflect unabsorbed light in the quantum dots of the present embodiments and allow the quantum dots to absorb the reflected light again. For example, the light diffusing agent may increase an amount of light absorbed by the quantum dots and increase light conversion efficiency of the curable composition.

The light diffusing agent may have an average particle diameter (D₅₀) of about 150 nm to about 250 nm, and for example, about 180 nm to about 230 nm. If the average particle diameter of the light diffusing agent is within any of the above ranges, the light diffusing agent may have a better or improved light diffusing effect and may increase light conversion efficiency.

The light diffusing agent may be included in an amount of about 1 wt % to about 20 wt %, for example, about 2 wt % to about 15 wt %, for example, about 3 wt % to about 10 wt % based on a total amount of the curable composition. If the light diffusing agent is included in an amount of less than about 1 wt % based on a total amount of the curable composition, it may difficult to obtain a light conversion efficiency improvement effect due to the utilization of the light diffusing agent, while if it is included in an amount of greater than about 20 wt %, there is a possibility that the quantum dots may be sedimented.

### Polymerization Initiator

The curable composition according to one or more embodiments may further include a polymerization initiator, for example, a photopolymerization initiator, a thermal polymerization initiator, or a combination thereof.

The photopolymerization initiator may be any suitable initiator for a photosensitive resin composition, for example an acetophenone-based compound, a benzophenone-based compound, a thioxanthone-based compound, a benzoin-based compound, a triazine-based compound, an oxime-based compound, an aminoketone-based compound, and/or the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and/or the like.

Examples of the benzoin-based compound may be benzoin, benzoin methyl ether, benzoin ethyl ether, benzoin isopropyl ether, benzoin isobutyl ether, benzyldimethylketal, and/or the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

Examples of the oxime-based compound may be O-acyloxime-based compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, 0-ethoxycarbonyl-α-oxyamino-1-phenylpropan-1-one, and/or the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and/or the like.

Examples of the aminoketone-based compound may be 2-benzyl-2-dimethylamino-1-(4-morpholinophenyl)-butanone-1, and/or the like.

The photopolymerization initiator may further include a carbazole-based compound, a diketone-based compound, a sulfonium borate-based compound, a diazo-based compound, an imidazole-based compound, a biimidazole-based compound, and/or the like, in addition to any of the above compounds.

The photopolymerization initiator may be utilized with a suitable photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and/or the like.

Examples of the thermal polymerization initiator may be peroxide, for example, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and/or the like, and 2,2′-azobis-2-methylpropinonitrile, but are not necessarily limited thereto, and any suitable compounds may be utilized.

The polymerization initiator may be included in an amount of about 0.1 wt % to about 5 wt %, for example, about 1 wt % to about 4 wt %, based on a total amount of the curable composition. If the polymerization initiator is included in any of the above ranges, it may be possible to obtain excellent or suitable reliability due to sufficient or suitable curing during exposure and/or thermal curing, and to prevent or reduce deterioration of transmittance due to non-reaction initiators, thereby preventing or reducing deterioration of optical characteristics of the quantum dots.

### Binder Resin

The curable composition according to one or more embodiments may further include a binder resin.

The binder resin may include an acrylic resin, a cardo-based resin, an epoxy resin, or a combination thereof.

The acrylic resin may be a copolymer of a first ethylenic unsaturated monomer and a second ethylenic unsaturated monomer that is copolymerizable therewith, and may be resin including at least one acryl-based repeating unit.

Examples of the acrylic resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and/or the like, but are not limited thereto, and may be utilized alone or as a mixture of two or more.

A weight average molecular weight of the acrylic resin may be about 5,000 g/mol to about 15,000 g/mol. If the acrylic resin has a weight average molecular weight within this range, close contacting properties to a substrate, physical and/or chemical properties may be improved, and suitable viscosity may be obtained.

An acid value of the acrylic resin may be about 80 mgKOH/g to about 130 mgKOH/g. If the acrylic resin has an acid value within this range, excellent or suitable resolution of a pixel may be obtained.

The cardo-based resin may be utilized in a suitable or comparable curable resin (and/or photosensitive resin) composition, for example, one suggested in Korean Patent Publication No. 10-2018-0067243, but is not limited thereto, the entire content of which is incorporated herein by reference.

The cardo-based resin may be, for example, prepared by mixing at least two of: a fluorene-containing compound such as 9,9-bis(4-oxiranylmethoxyphenyl)fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and/or tetrahydrophthalic anhydride; a glycol compound such as ethylene glycol, propylene glycol, and/or polyethylene glycol; an alcohol compound such as methanol, ethanol, propanol, n-butanol, cyclohexanol, and/or benzylalcohol; a solvent-based compound such as propylene glycol methylethylacetate, and/or N-methylpyrrolidone; a phosphorus compound such as triphenylphosphine; and an amine and/or ammonium salt compound such as tetramethylammonium chloride, tetraethylammonium bromide, benzyldiethylamine, triethylamine, tributylamine, and/or benzyltriethylammonium chloride.

A weight average molecular weight of the cardo-based binder resin may be about 500 g/mol to about 50,000 g/mol, for example about 1,000 g/mol to about 30,000 g/mol. If the weight average molecular weight of the cardo-based binder resin is within any of these ranges, a satisfactory or suitable pattern may be formed without (or substantially without) a residue during a production of a cured layer and/or without (or substantially without) losing a film thickness during development of the curable composition.

If the binder resin is a cardo-based resin, the curable composition including the same, for example, the photosensitive resin composition, may have excellent or suitable developability and/or sensitivity during photo-curing and thus, fine pattern-forming capability.

The epoxy resin may be a thermally polymerizable monomer and/or oligomer, and may include a compound having a carbon-carbon unsaturated bond and/or a carbon-carbon cyclic bond.

The epoxy resin may further include a bisphenyl epoxy resin, a cresol novolac epoxy resin, a bisphenol A epoxy resin, a bisphenol F epoxy resin, a phenol novolac epoxy resin, a cyclic aliphatic epoxy resin, and/or an aliphatic polyglycidyl ether, but is not necessarily limited thereto.

As commercially available products of the compounds, a bisphenyl epoxy resin may be YX4000, YX4000H, YL6121H, YL6640, and/or YL6677 of Yuka Shell Epoxy; a cresol novolac epoxy resin may be EOCN-102, EOCN-103S, EOCN-104S, EOCN-1020, EOCN-1025, and/or EOCN-1027 of Nippon Kayaku Co., Ltd. and/or EPIKOTE 180S75, and/or the like of Yuka Shell Epoxy; a bisphenol A epoxy resin may be EPIKOTE 1001, 1002, 1003, 1004, 1007, 1009, 1010, and/or 828 of Yuka Shell Epoxy; a bisphenol F epoxy resin may be EPIKOTE 807 and 834 of Yuka Shell Epoxy; a phenol novolac epoxy resin may be EPIKOTE 152, 154, and/or 157H65 of Yuka Shell Epoxy and EPPN 201, 202 of Nippon Kayaku Co., Ltd. and/or EPPN 201, 202 of Nippon Kayaku Co., Ltd.; a cyclic aliphatic epoxy resin may be CY175, CY177, and/or CY179 of CIBA-GEIGY A.G, ERL-4234, ERL-4299, ERL-4221 and/or ERL-4206 of U.C.C., Showdyne 509 of Showa Denko K.K., Araldite CY-182, CY-192 and/or CY-184 of CIBA-GEIGY A.G, EPICLON 200 and/or 400 of DIC Corporation., EPIKOTE 871 and/or 872, and/or EP1032H60 of Yuka Shell Epoxy, ED-5661 and/or ED-5662 of Celanese Corporation; an aliphatic polyglycidylether may be EPIKOTE 190P and/or 191P of Yuka Shell Epoxy, EPOLITE 100MF of Kyoeisha Yushi Kagaku Kogyo Co., Ltd., EPIOL TMP of Nihon Yushi K. K., and/or the like.

For example, if (e.g., when) the curable composition according to one or more embodiments is a solvent-free curable composition, the binder resin may be included in an amount of about 0.5 wt % to about 10 wt %, for example, about 1 wt % to about 5 wt %, based on a total amount of the curable composition. In this case, the heat resistance and/or the chemical resistance of the solvent-free curable composition may be improved, as well as the storage stability of the composition.

For example, if (e.g., when) the curable composition according to one or more embodiments is a curable composition including a solvent, the binder resin may be included in an amount of about 1 wt % to about 30 wt %, for example, about 3 wt % to about 20 wt %, based on a total amount of the curable composition. In this case, it may improve pattern characteristics, heat resistance, and/or chemical resistance.

### Other Additives

For further stability and dispersion improvement of the quantum dot, the curable composition according to one or more embodiments may further include a polymerization inhibitor.

The polymerization inhibitor may include a hydroquinone-based compound, a catechol-based compound, or a combination thereof, but is not necessarily limited thereto. If (e.g., when) the curable composition according to one or more embodiments further includes the hydroquinone-based compound, the catechol-based compound, or the combination thereof, room temperature cross-linking during exposure after coating the curable composition may be prevented or reduced.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, but are not necessarily limited thereto.

The hydroquinone-based compound, the catechol-based compound, or the combination thereof may be utilized in a form of dispersion. The polymerization inhibitor in a form of dispersion may be included in an amount of about 0.001 wt % to about 3 wt %, for example about 0.01 wt % to about 2 wt % based on a total amount of the curable composition. If (e.g., when) the polymerization inhibitor is included in any of the above ranges, passage of time at room temperature may be solved or improved and concurrently (e.g., simultaneously) sensitivity deterioration and surface delamination phenomenon may be prevented or reduced.

In some embodiments, the curable composition according to one or more embodiments may further include malonic acid; 3-amino-1,2-propanediol; a silane-based coupling agent; a leveling agent; a fluorine-based surfactant; or a combination thereof, to further improve heat resistance and/or reliability.

For example, the curable composition according to embodiments may further include a silane-based coupling agent having a reactive substituent such as a vinyl group, a carboxyl group, a methacryloxy group, an isocyanate group, an epoxy group, and/or the like, to further improve close contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexylethyltrimethoxysilane, and/or the like, and these may be utilized alone or in a mixture of two or more.

The silane-based coupling agent may be utilized in an amount of about 0.01 parts by weight to about 10 parts by weight based on 100 parts by weight of the curable composition. If the silane-based coupling agent is included within this range, close contacting properties, storage capability, and/or the like may be further improved.

In some embodiments, the curable composition may further include a surfactant, for example a fluorine-based surfactant, to further improve coating properties and/or inhibit or reduce generation of spots, that is, improve leveling performance.

The fluorine-based surfactant may have a low weight average molecular weight of about 4,000 g/mol to about 10,000 g/mol, and for example, about 6,000 g/mol to about 10,000 g/mol. In some embodiments, the fluorine-based surfactant may have a surface tension of about 18 mN/m to about 23 mN/m (measured in a 0.1% polyethylene glycol monomethylether acetate (PGMEA) solution). If the fluorine-based surfactant has a weight average molecular weight and a surface tension within the above respective ranges, leveling performance may be further improved, and excellent or suitable characteristics may be provided if (e.g., when) slit coating as high-speed coating is applied, because film defects may be less generated (e.g., to a lesser extent) by preventing or reducing spot generation during the high-speed coating and suppressing or reduction of vapor generation.

Examples of the fluorine-based surfactant may be, BM-1000, and BM-1100 (Bodo MöllerChemie); MEGAFACE™@ F 142D, F 172, F 173, and F 183 of DIC Corporation); FLUORAD™ FC-135, FLUORAD™ FC-170C, FLUORAD™ FC-430, and FLUORAD™ FC-431 (Sumitomo 3M Co., Ltd.); SURFLON™ S-112, SURFLON™ 5-113, SURFLON™ S-131, SURFLON™ S-141, and/or SURFLON™ S-145 (ASAHI Glass Co., Ltd.); and SH-28PA, SH-190, SH-193, SZ-6032, and/or SF-8428, and/or the like (Dow Corning Toray Silicone Co., Ltd.); F-482, F-484, F-478, F-554 and/or the like of DIC Corporation.

In some embodiments, the curable composition according to one or more embodiments may include a silicone-based surfactant in addition to the fluorine-based surfactant. Examples of the silicone-based surfactant may be TSF400, TSF401, TSF410, TSF4440, and/or the like of GE Toshiba Silicones Co., Ltd., but are not limited thereto.

The surfactant may be included in an amount of about 0.01 parts by weight to about 5 parts by weight, for example about 0.1 parts by weight to about 2 parts by weight based on 100 parts by weight of the curable composition. If the surfactant is included within any of the above ranges, foreign materials are less produced (e.g., to a lesser extent) in a sprayed composition.

In some embodiments, the curable composition according to one or more embodiments may further include one or more other suitable additives such as an antioxidant, a stabilizer, and/or the like in a set or predetermined amount, so long as the properties of the curable composition are not substantially deteriorated.

### Solvent

In some embodiments, the curable composition according to one or more embodiments may further include a solvent.

The solvent may, for example, include alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl ester such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; and/or ketonate esters such as ethyl pyruvate, and/or the like, and in some embodiments, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but is not limited thereto.

For example, the solvent may be selected from among suitable glycol ethers such as ethylene glycol monoethylether, ethylene diglycolmethylethylether, and/or the like; ethylene glycol alkylether acetates such as ethyl cellosolve acetate, and/or the like; esters such as 2-hydroxy ethyl propionate, and/or the like; carbitols such as diethylene glycol monomethylether, and/or the like; propylene glycol alkylether acetates such as propylene glycol monomethylether acetate, propylene glycol propylether acetate, and/or the like; alcohols such as ethanol, and/or the like, and combinations thereof.

For example, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount of about 40 wt % to about 80 wt %, for example, about 45 wt % to about 80 wt %, based on a total amount of the curable composition. If the solvent is within any of these ranges, the solvent-type or kind curable composition may have appropriate or suitable viscosity and thus may have excellent or suitable coating property if (e.g., when) coated in a large area through spin-coating and/or slit-coating.

One or more embodiments provide a cured layer produced utilizing the curable composition, and a display device including the cured layer. Herein, the cured layer may have a reflectance measured by the SCI (Specular Component Included) method of 30% or less (for example, less than 30%) and a reflectance measured by the SCE (Specular Component Excluded) method of less than or equal to about 25%.

One of methods of producing the cured layer may include coating the curable composition and solvent-type or kind curable composition on a substrate utilizing an ink-jet spraying method to form a pattern (S1); and curing the pattern (S2).

### (S1) Formation of Pattern

The curable composition may desirably, for example, be coated to be about 0.5 μm to about 20 μm on a substrate in an ink-jet spraying method. The ink-jet spraying method may form a pattern by spraying a single color per each nozzle and thus repeating the spraying as many times as there are needed (e.g., desired) number of colors, but the pattern may be formed by concurrently (e.g., simultaneously) spraying the needed number of colors through each ink-jet nozzle in order to (e.g., in an effort to) reduce processes.

### (S2) Curing

The obtained pattern is cured to obtain a pixel. Herein, the curing method may be thermal curing and/or photocuring process. The thermal curing process may be performed at a temperature of greater than or equal to about 100° C., for example, in a range of about 100° C. to about 300° C., or in a range of about 160° C. to about 250° C. The photocuring process may include irradiating an actinic ray such as a UV ray of about 190 nm to about 450 nm, for example about 200 nm to about 400 nm. As a light source utilized for irradiation, a low-pressure mercury lamp, high-pressure mercury lamp, ultra-high-pressure mercury lamp, metal halide lamp, argon gas laser, i-line, KrF, ArF, I-ArF, EUV, X-ray, electron beam, etc. may be utilized as needed.

Accordingly to one or more embodiments, another method of producing the cured layer may include producing a cured layer utilizing the aforementioned curable composition and/or solvent-type or kind curable composition by a lithographic method as follows.

### (1) Coating and Film Formation

The curable composition is coated to have a desired or suitable thickness, for example, a thickness in a range of about 2 μm to about 10 μm, on a substrate which undergoes a set or predetermined pretreatment, utilizing a spin and/or slit coating method, a roll coating method, a screen-printing method, an applicator method, and/or the like. Then, the coated substrate is heated at a temperature of about 70° C. to about 90° C. for about 1 minute to about 10 minutes to remove a solvent and to form a film.

### (2) Exposure

The resultant film is irradiated by an actinic ray such as a UV ray of about 190 nm to about 450 nm, for example about 200 nm to about 400 nm, after putting a mask with a set or predetermined shape to form a desired or suitable pattern. As a light source utilized for irradiation, a low-pressure mercury lamp, high-pressure mercury lamp, ultra high-pressure mercury lamp, metal halide lamp, argon gas laser, i-line, KrF, ArF, I-ArF, EUV, X-ray, electron beam, etc. may be utilized as needed.

Exposure process uses, for example, a light dose of 500 mJ/cm² or less (with a 365 nm sensor) if (e.g., when) a high-pressure mercury lamp is utilized. However, the light dose may vary depending on types (kinds) of each component of the curable composition, its combination ratio, and/or a dry film thickness.

### (3) Development

After the exposure process, an alkali aqueous solution is utilized to develop the exposed film by dissolving and removing an unnecessary (e.g., unexposed) part except the exposed part, and forming an image pattern. In the present embodiments, if (e.g., when) the alkali developing solution is utilized for the development, an unexposed region is dissolved, and an image color filter pattern is formed.

### (4) Post-Treatment

The developed image pattern may be heated again and/or irradiated by an actinic ray and/or the like for curing, in order to (e.g., in an effort to) accomplish excellent or suitable quality in terms of heat resistance, light resistance, close contacting properties, crack-resistance, chemical resistance, high strength, storage stability, and/or the like.

Hereinafter, the present disclosure is illustrated in more detail with reference to examples. These examples, however, are not in any sense to be interpreted as limiting the scope of the present disclosure.

### Preparation of Surface-modified Quantum Dot Dispersion

### Preparation Example 1

After putting a magnetic bar in a 3-necked round bottom flask, a red quantum dot dispersion solution (quantum dot solid content (e.g., amount): 23 wt %, InP/ZnSe/ZnS, Hansol Chemical) was added thereto. Subsequently, a compound represented by Chemical Formula Q (as a ligand) was added thereto and then, stirred at 80° C. under a nitrogen atmosphere. After the reaction was completed, the quantum dot reaction was cooled to room temperature (23° C.) and then, added to cyclohexane, catching (e.g., forming) precipitates. The precipitates were separated from the cyclohexane through the centrifugation and then, sufficiently or suitably dried in a vacuum oven for 24 hours, obtaining surface-modified quantum dots.

The surface-modified red quantum dots were stirred in a polymerizable compound for 12 hours, obtaining surface-modified quantum dot dispersion (QD solid: 23 wt %).

### Synthesis of Compound Represented by Chemical Formula Q

100 g of PH-4 (Hannong Chemicals Inc.) was placed in a 2-necked round bottom flask and sufficiently or suitably dissolved in 300 mL of THF. Subsequently, 15.4 g of NaOH and 100 mL of water were added thereto at 0° C. and sufficiently or suitably dissolved therein until a transparent solution was obtained. Then, a solution prepared by dissolving 73 g of para-toluene sulfonic chloride in 100 mL of THE was slowly injected thereinto at 0° C. Herein, the injection proceeded for 1 hour, and then, the obtained mixture was stirred at room temperature for 12 hours. After the reaction was completed, an excessive amount of methylene chloride was added thereto and then, stirred, and a NaHCO₃ saturated solution was added thereto and then, proceeded with extraction, titration, and moisture removal. After removing the solvent, the residue was dried in a dry oven for 24 hours. 50 g of the dried product was placed in a 2-necked round bottom flask and then, sufficiently or suitably stirred in 300 mL of ethanol. Subsequently, 27 g of thiourea was added thereto for dispersion and then, refluxed at 80° C. for 12 hours. After injecting an aqueous solution obtained by dissolving 4.4 g of NaOH in 20 mL of water thereinto, an excessive amount of methylene chloride was added thereto, while further stirring for 5 hours, and then, stirred, and a hydrochloric acid aqueous solution was added thereto and then, proceeded sequentially with extraction, titration, moisture removal, and solvent removal. Drying in a vacuum oven was performed for 24 hours, obtaining a compound represented by Chemical Formula Q.

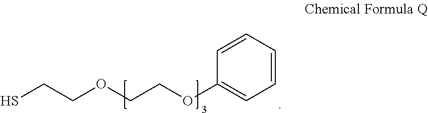

### Preparation of Curable Compositions

### Examples 1 to 9 and Comparative Examples 1 to 3

Each of the curable compositions of Examples 1 to 9 and Comparative Examples 1 to 3 was prepared to have a composition shown in Tables 1 and 2 by utilizing the following components.

For example, the quantum dot dispersion was weighed and then, mixed with a polymerizable compound and diluted with an electrolyte and then, stirred for 5 minutes. Subsequently, a polymerization initiator was added thereto, and a light diffusing agent was added thereto. Then, the corresponding crude liquid was stirred for 1 hour, preparing a curable composition.

### (A) Quantum Dots

Surface-modified red quantum dot dispersion prepared from Preparation Example 1

### (B) Polymerizable Compound

Compound represented by Chemical Formula 2-2 (M200, Miwon Specialty Chemical Co.)

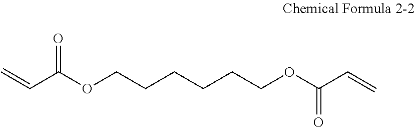 [SMILES: C=CC(=O)OCCCCCCOC(=O)C=C]

### (C) Additive

(C-1) Hexamethyldisiloxane (Sigma-Aldrich Corporation) (molecular weight: 162.38 g/mol)
(C-2) 1,1,3,3-Tetramethyl-1,3-bis(trimethylsiloxy)disiloxane (Sigma-Aldrich Corporation) (molecular weight: 310.13 g/mol)

### (D) Photopolymerization Initiator

TPO-L (Polynetron Co.)

### (E) Light Diffusing Agent

Titanium dioxide dispersion (TiO₂ solid content (e.g., amount): 20 wt %, average particle diameter: 200 nm, Ditto Technology Co., Ltd.)

TABLE 1
unit: wt %

| | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|
| (A) Quantum dot | | 36 | 36 | 36 | 39.4 | 39.4 | 39.4 | 39.4 | 36 | 36 |
| dispersion | | | | | | | | | | |
| (B) Polymerizable | | 53.39 | 50.58 | 44.96 | 47.61 | 49.41 | 46.023 | 45.276 | 53.952 | 44.398 |
| compound | | | | | | | | | | |
| (C) Additive | (C-1) | 2.81 | 5.62 | 11.24 | 5.29 | 5.49 | 6.877 | 8.624 | 2.248 | 11.802 |
| | (C-2) | | | | | | | | | |

| | | | | | | | | | |
|---|---|---|---|---|---|---|---|---|---|
| (D) | 3 | 3 | 3 | 3 | 3 | 3 | 2 | 3 | 3 |
| Photopolymerization | | | | | | | | | |
| initiator | | | | | | | | | |
| (E) Light diffusing | 4.8 | 4.8 | 4.8 | 4.7 | 2.7 | 4.7 | 4.7 | 4.8 | 4.8 |
| agent | | | | | | | | | |

TABLE 2
unit: wt %

| | | Comp. | Comp. | Comp. |
|---|---|---|---|---|
| | | Ex. 1 | Ex. 2 | Ex. 3 |
| (A) Quantum dot dispersion | | 36 | 36 | 36 |
| (B) Polymerizable compound | | 56.2 | — | 53.39 |
| (C) Additive | (C-1) | — | 56.2 | — |
| | (C-2) | — | — | 2.81 |

| | | | |
|---|---|---|---|
| (D) Photopolymerization initiator | 3 | 3 | 3 |
| (E) Light diffusing agent | 4.8 | 4.8 | 4.8 |

### Evaluation 1: Evaluation of Optical Characteristics and Viscosity of Curable Composition

Each of the curable compositions of Examples 1 to 9 and Comparative Examples 1 to 3 was measured with respect to light efficiency after exposure and curing by utilizing a spectrophotometer (CM-3600A, Konica Minolta, Inc.), and the results are shown in Table 3.

In some embodiments, each of the curable compositions according to Examples 1 to 9 and Comparative Examples 1 to 3 was measured with respect to initial viscosity at 25° C. by utilizing a viscometer (23 rpm, RV-2spindle, DV-H, Brookfield Corp.), and the results are shown in Table 3.

TABLE 3

| | Light efficiency (%) | Viscosity (cPs) |
|---|---|---|
| Ex. 1 | 39.6 | 22.6 |
| Ex. 2 | 39.8 | 20.2 |
| Ex. 3 | 40.8 | 18.1 |
| Ex. 4 | 40.9 | 24.7 |
| Ex. 5 | 38.6 | 22.0 |
| Ex. 6 | 41.3 | 23.0 |
| Ex. 7 | 42.4 | 20.8 |
| Ex. 8 | 38.1 | 23.2 |
| Ex. 9 | 38.0 | 23.1 |
| Comp. Ex. 1 | 37.2 | 24.5 |
| Comp. Ex. 2 | 34.3 | 24.2 |
| Comp. Ex. 3 | 35.4 | 25.1 |

Referring to Table 3, each of the curable compositions of Examples 1 to 9, compared with the curable compositions of Comparative Examples 1 to 3, exhibited insignificant or suitable deterioration of the light efficiency after the curing.

### Evaluation 2: Reflectance Evaluation of Curable Composition

Each of the curable compositions of Examples 1 to 4, 6, and 7 and Comparative Examples 1 to 3 was measured with respect to reflectance (SCI, SCE) after the exposure and curing by utilizing a spectrophotometer (CM-3600A, Konica Minolta, Inc.), and the results are shown in Table 4.

TABLE 4

| | SCI (%) | SCE (%) |
|---|---|---|
| Ex. 1 | 28.38 | 22.95 |
| Ex. 2 | 28.61 | 22.91 |
| Ex. 3 | 28.25 | 22.76 |
| Ex. 4 | 29.62 | 24.21 |
| Ex. 6 | 28.79 | 23.31 |
| Ex. 7 | 29.41 | 24.09 |
| Comp. Ex. 1 | 30.52 | 26.39 |
| Comp. Ex. 2 | 31.27 | 26.12 |
| Comp. Ex. 3 | 32.03 | 26.51 |

Referring to Table 4, the curable composition of one embodiment, compared with the curable compositions of Comparative Examples 1 to 3, exhibited an excellent or suitable reflectance reduction effect.

In the present disclosure, if (e.g., when) dots or particles are spherical, the term “diameter” indicates a particle diameter or an average particle diameter, and it (e.g., when) the dots or particles are non-spherical, the term “diameter” indicates a major axis length or an average major axis length. In some embodiments, the average particle diameter may be measured by a method well suitable to those skilled in the art, for example, may be measured by a particle size analyzer, or may be measured by a transmission electron microscopic image or a scanning electron microscopic image. In some embodiments, it is possible to obtain an average particle diameter value by measuring utilizing a dynamic light scattering method, performing data analysis, counting the number of particles for each particle size range, and calculating from this. As utilized herein, if (e.g., when) a definition is not otherwise provided, the average particle diameter may refer to a diameter (D50) of particles having a cumulative volume of 50 vol % in a particle size distribution.

A display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

While this present disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and their equivalents. Therefore, the aforementioned embodiments should be understood to be example but not limiting the present disclosure in any way.

What is claimed is:

1. A curable composition, comprising
(A) quantum dots;
(B) a polymerizable compound; and
(C) a compound represented by Chemical Formula 1 having a weight average molecular weight of less than or equal to about 300 g/mol: 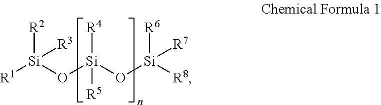
wherein, in Chemical Formula 1,
R¹ to R⁸ are each independently a hydrogen atom, a hydroxy group, an amine group, a substituted or unsubstituted C1 to C20 alkyl group, a substituted or unsubstituted C3 to C20 cycloalkyl group, or a substituted or unsubstituted C6 to C20 aryl group, and
n is an integer of 0 or 1.

2. The curable composition as claimed in claim 1, wherein
R¹ to R⁸ are each independently a substituted or unsubstituted C1 to C20 alkyl group.

3. The curable composition as claimed in claim 1, wherein
n is an integer of 0.

4. The curable composition as claimed in claim 1, wherein
the compound represented by Chemical Formula 1 has a weight average molecular weight of about 162 g/mol to about 300 g/mol.

5. The curable composition as claimed in claim 1, wherein
the compound represented by Chemical Formula 1 is comprised in an amount of about 1 wt % to about 15 wt %.

6. The curable composition as claimed in claim 1, wherein
the polymerizable compound and the compound represented by Chemical Formula 1 are in a weight ratio of about 95:5 to about 80:20.

7. The curable composition as claimed in claim 1, wherein
the polymerizable compound is represented by Chemical Formula 2: 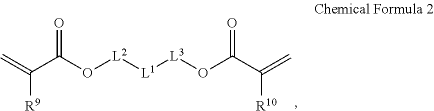
wherein, in Chemical Formula 2,
L¹ is a substituted or unsubstituted C1 to C10 alkylene group, a substituted or unsubstituted C3 to C20 cycloalkylene group, or an ether group (*—O—*),
L² and L³ are each independently a single bond or a substituted or unsubstituted C1 to C10 alkylene group, and
R⁹ and R¹⁰ are each independently a hydrogen atom, a substituted or unsubstituted C1 to C20 alkyl group, a substituted or unsubstituted C3 to C20 cycloalkyl group, or a substituted or unsubstituted C6 to C20 aryl group.

8. The curable composition as claimed in claim 1, wherein
the curable composition is a solvent-free curable composition.

9. The curable composition as claimed in claim 8, wherein
the solvent-free curable composition comprises:
about 5 wt % to about 60 wt % of the (A) quantum dots;
about 30 wt % to about 85 wt % of the (B) polymerizable compound; and
about 1 wt % to about 15 wt % of the (C) compound represented by Chemical Formula 1,
based on a total amount of the solvent-free curable composition.

10. The curable composition as claimed in claim 1, wherein
the curable composition further comprises a polymerization initiator, a light diffusing agent, a polymerization inhibitor, or a combination thereof.

11. The curable composition as claimed in claim 10, wherein
the light diffusing agent comprises barium sulfate, calcium carbonate, titanium dioxide, zirconia, or a combination thereof.

12. The curable composition as claimed in claim 1, wherein
the curable composition further comprises a solvent.

13. The curable composition as claimed in claim 1, wherein
the curable composition further comprises malonic acid; 3-amino-1,2-propanediol; a silane-based coupling agent; a leveling agent; a fluorine-based surfactant; or a combination thereof.

14. A cured layer produced utilizing the curable composition as claimed in claim 1.

15. The cured layer as claimed in claim 14, wherein
the cured layer has a reflectance as measured by a specular component excluded (SCE) method of less than or equal to about 25%.

16. A display device comprising the cured layer as claimed in claim 14.
